(19) United States
(12) Patent Application Publication
(10) Pub. No.: US 2018/0147820 A1
(43) Pub. Date: May 31, 2018

(54) MULTILAYER MEMBRANE

(71) Applicant: SAINT-GOBAIN ISOVER, Courbevoie (FR)

(72) Inventors: Charles LEYDER, Paris (FR); Antoine DIGUET, Paris (FR)

(73) Assignee: SAINT-GOBAIN ISOVER, Courbevoie (FR)

(21) Appl. No.: 15/577,493

(22) PCT Filed: Jun. 1, 2016
(86) PCT No.: PCT/FR2016/051304

§ 371 Date: Nov. 28, 2017

(30) Foreign Application Priority Data
Jun. 2, 2015 (FR) 1555002

(51) Int. Cl. B32B 27/08; B32B 7/12; B32B 5/18; C23C 14/35; C08F 222/10; C08J 7/04; F16L 59/02; F16L 59/065

(52) U.S. Cl. CPC B32B 27/08; C08J 2433/08; B32B 5/18; C23C 14/35; C08F 222/10; C08J 7/045; F16L 59/029; F16L 59/065; B32B 2255/205; B32B 2307/31; B32B 2307/7244; B32B 2307/7246; B32B 2419/00; B32B 2309/105; B32B 2307/538; C08J 2367/02; B32B 7/12

(57) ABSTRACT

A multilayer membrane is intended to be used as an envelope for a thermal insulation panel, in particular a VIP-type panel. The multilayer membrane includes a support layer, at least one planarizing layer defining a planarized surface, and at least one thin metallic layer.

The present invention relates to the membranes used as an envelope in thermal insulation panels, in particular panels of VIP (vacuum insulation panel) type. It relates in particular to membranes comprising, besides a support layer, at least one planarizing layer and at least one thin metallic layer. The invention also relates to a process for manufacturing these membranes.

### PRIOR ART

VIP-type panels are formed in a known manner: from a membrane envelope that ensures the gas tightness and from a rigid panel made of a porous material having insulating properties, placed inside this envelope and kept under vacuum by means of this envelope. The porous panel, which is usually made of a material such as fumed silica, an aerogel, perlite, glass fibers, gives its shape to the panel and confers its mechanical strength thereon.

Such panels are useful for the thermal insulation of a wall due to their high insulating performance for a reduced thickness and a reduced space requirement.

When VIP-type panels are manufactured, the gases are evacuated from the insulating porous material before the latter is packaged under vacuum in a flexible barrier envelope. This envelope is generally formed from a membrane comprising a heat-sealable film, and which may comprise several layers of different materials.

The barrier membranes, that envelop the insulating material, must satisfy numerous constraints in order to avoid a degradation of the insulating properties of the VIP over time: they must be gastight, in particular with respect to water vapor and to oxygen, so as to avoid the penetration of the gases inside the membrane and to maintain a high degree of vacuum. The barrier membranes must have a satisfactory mechanical strength in order to avoid a degradation of their performance during the handling of the panels, but also a high flexibility so as to allow the envelopment of the insulation panel by the membrane. In the case of insulation panels intended for the construction sector, these membranes must retain their barrier properties over very long periods of time, of from one to several decades.

Preferably, it is desired for the barrier membranes to be designed to prevent the formation of thermal bridges at the edges.

The barrier membranes from the prior art, as described for example in US 2004/0253406, are multilayer materials generally comprising at least:
a support layer made of polymer material,
a layer providing gas tightness, which may be a metallic foil, such as an aluminum foil, or a thin layer resulting from the deposition of a metal or of a metal oxide,
a heat-sealable layer that makes it possible to seal the barrier membrane around the insulating material in a leaktight manner.

Numerous variants have been described in the prior art with a view to improving the barrier properties and/or the durability of these membranes.

For example, EP 2 508 785 teaches an (outer) support layer resulting from the co-extrusion of a nylon resin, of an ethylene/vinyl alcohol copolymer, and of a second nylon resin.

In the packaging field, a semi-transparent multilayer film based on non-stoichiometric metal oxides is taught by US 2005/0037217.

The layer providing the gas tightness has one particular difficulty: indeed, when it is composed of a continuous metal foil, the barrier properties of the insulating panels, taken individually, are excellent. However, during the assembling of insulating panels, thermal bridges form at the joining surfaces between two panels. These thermal bridges are even greater when the metallic layer is thick. In particular, for a conventional thickness of a metal foil of the order of 5 to 50 μm, the resulting thermal bridges are not compatible with the level of thermal insulation required for VIP panels. In order to overcome this problem, it has been proposed (US 2002/0018891) to produce the gastight layer by depositing a thin layer of a metal or of a metal oxide on the support layer or on an intermediate layer. Indeed, the reduced thickness of metal which may be obtained by these techniques makes it possible to reduce the barrier effect at the joining faces of the panels. However, the deposition techniques do not make it possible to obtain a layer having a perfect continuity and the gas barrier effect is reduced by the presence of small-sized orifices.

Improvements have been proposed in the prior art, and in particular:

JP2005307995 teaches a barrier membrane comprising, in order: a PET base material, deposited on which is a thin layer of metal or of metal oxide, deposited by chemical vapor deposition, then a protective layer made of polyacrylic resin, which is a copolymer with a polyvinyl alcohol (PVA), and finally a heat-sealable layer. The role of the polyacrylic resin is to protect the multilayer against peeling during the folding of the material and against frictional wear.

JP2006046442 describes a multilayer barrier membrane comprising, in order: a PET base material, deposited on which is a thin layer of metal or of metal oxide, deposited by chemical vapor deposition, a protective layer made of polyacrylic resin copolymerized with PVA and highly crosslinked, and finally a heat-sealable layer. The crosslinked polyacrylic layer penetrates into the metallic layer and is used to compensate for the micro-orifices of the metallic deposition.

However, the gas barrier properties of acrylic resins copolymerized with PVA are insufficient to compensate for the discontinuous nature of the metallic film in a satisfactory manner. Documents JP2005307995 and JP2006046442 essentially relate to an application of the insulating panels to domestic electrical appliances for which the service life constraints are lower than in the construction sector. The problem of thermal bridges is also less important in these applications relative to the assemblies that are used in the construction industry.

None of these solutions is, to date, satisfactory. The objective of the invention has been to overcome the drawbacks of the prior art. The solution proposed is based on the use of a planarizing layer between the support layer and the gastight layer.

It was in no way foreseeable that the use of a planarizing layer, associated with a layer resulting from the deposition of a metal or of a metal oxide, would make it possible to very significantly increase the gas barrier properties of the metallic layer.

### SUMMARY OF THE INVENTION

A first subject of the invention is a multilayer membrane comprising a stack of layers, including one heat-sealable layer forming a peripheral face of the multilayer membrane and at least, in order, the following sequence:
a support layer made of polymer material,
a metallic layer made of at least one material selected from: a metal and a metal oxide, having a thickness less than or equal to 200 nm,

characterized in that it comprises at least one planarizing layer between the support layer and the metallic layer, the planarizing layer defining a planarized surface which has a mean surface roughness Rq less than or equal to 1 nm.

Within the context of the invention, Rq is the root-mean-square deviation as defined in the ISO 4287 standard, measured by atomic force microscopy (AFM) over a surface area of 5×5 μm².

Another subject of the invention is a vacuum insulation panel comprising at least one rigid panel made of a porous material having insulating properties and an envelope composed of at least one multilayer membrane according to the invention.

Preferably, in a vacuum insulation panel according to the invention, the rigid panel made of porous material comprises a desiccant material that makes it possible to absorb the residual water vapor capable of passing through the envelope, such as for example calcium oxide (CaO).

Furthermore, a vacuum insulation panel according to the invention may comprise, in addition, a coating of fabric type, in particular a glass fiber fabric, which may be linked to the multilayer membrane according to the invention or be assembled around the panel independently of the multilayer membrane according to the invention.

Another subject of the invention is a process for manufacturing a multilayer membrane according to the invention, this process comprising the provision of at least one support layer and the deposition of at least one metallic layer having a thickness less than or equal to 200 nm, this process being characterized in that it comprises the deposition of a planarizing layer between the support layer and the metallic layer.

Another subject of the invention is the use of a planarizing layer in a multilayer membrane of a vacuum insulation panel, between a support layer and a metallic layer having a thickness less than or equal to 200 nm, the planarizing layer defining a planarized surface which has a mean surface roughness Rq less than or equal to 1 nm, in order to increase the gas tightness of the membrane.

Another subject of the invention is the use of a multilayer membrane according to the invention as all or part of an envelope of a vacuum insulation panel.

According to one preferred embodiment, the planarizing layer defines a planarized surface which has a mean surface roughness Rq less than or equal to 0.5 nm.

According to one preferred embodiment, the planarizing layer results from the curing of a resin composition comprising one or more precursors of polymers selected from: polyesters, polyurethanes, polyester/polyurethane copolymers, silanes, siloxanes, silane-modified polyesters, silane-modified polyurethanes, polyester/siloxane copolymers and polyurethane/siloxane copolymers.

According to one preferred embodiment, the planarizing layer results from the curing of a resin composition comprising one or more precursors of polymers selected from: alkyl acrylates, alkyl methacrylates, urethanes/acrylates and urethanes/methacrylates.

According to one preferred embodiment, the planarizing layer results from the curing of a resin composition comprising at least:
a tetrafunctional urethane/alkyl (meth)acrylate oligomer,
a difunctional alkyl (meth)acrylate monomer,
a trimethylolpropane triacrylate monomer.

According to one preferred embodiment, the planarizing layer has a thickness between 0.1 μm and 100 μm, preferably between 0.5 μm and 25 μm, more preferably still between 1 μm and 5 μm.

According to one preferred embodiment, the metallic layer is made of aluminum.

According to one preferred embodiment, the support layer is based on polyethylene terephthalate.

According to one preferred embodiment, the stack of a planarizing layer and of a metallic layer of at least one metal or one metal oxide having a thickness less than or equal to 200 nm, defines a gastight module, the multilayer membrane comprising at least, in order:
a support layer made of polymer material,
a first gastight module,
a second gastight module, identical to or different from the first gastight module.

According to one preferred embodiment, the stack of a support layer made of polymer material, of a planarizing layer and of a metallic layer of at least one metal or one metal oxide having a thickness less than or equal to 200 nm, defines a supported module, the multilayer membrane comprising at least, in order:
a first supported module,
an adhesive layer,
a second supported module, identical to or different from the first supported module.

According to the latter embodiment, advantageously, the multilayer membrane comprises at least, in order:
a first supported module,
a first adhesive layer,
a second supported module,
a second adhesive layer,
a third supported module, identical to or different from the first supported module, identical to or different from the second supported module.

According to one preferred embodiment of the process, the deposition of the planarizing layer is carried out by a liquid route, in particular by roll coating or brush coating, slot-die coating, vaporization, dip coating, spin coating or Meyer rod coating.

According to one preferred embodiment of the process, the deposition of the metallic layer is carried out by evaporation or sputtering, in particular magnetron sputtering.

The insulation system according to the invention has many advantages. An increase in the gas (water vapor, oxygen) barrier properties of the membranes, and also a reduction in the phenomena of thermal bridges on the assemblies of VIP panels are observed. The mechanical strength and flexibility properties of the membranes of the invention are also very satisfactory.

### FIGURES

FIGS. 1A, 1B and 2 to 4: schematic cross-sectional views of various variants of membranes according to the invention.

To make them easier to read, in the various figures, the same numbering is used to denote the same part. The thicknesses of the various layers represented in the figures do not correspond to the actual thicknesses of the materials of the invention nor to the relative proportions of the thicknesses of the various layers.

### DETAILED DESCRIPTION

In the present description, the expression “polymer” denotes both homopolymers and copolymers. It includes mixtures of polymers, oligomers, mixtures of monomers, oligomers and polymers.

The expression “consists essentially of” or “is constituted essentially of” followed by one or more features means that, besides the components or steps explicitly listed, components or steps that do not significantly modify the properties and features of the invention may be included in the process or the material of the invention.

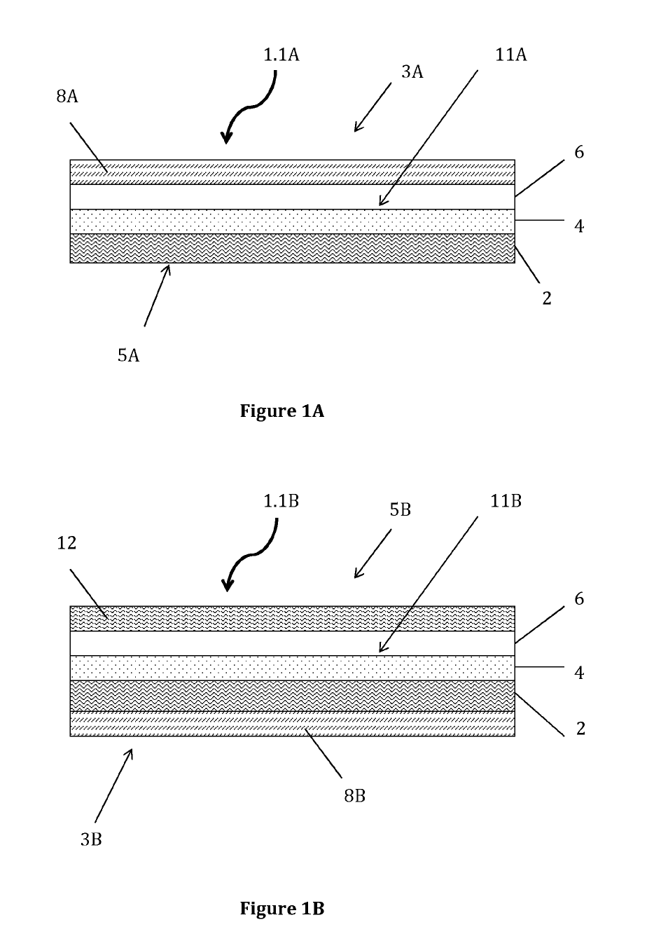

In FIG. 1A and as illustrated by example 5 from the experimental section, a multilayer membrane 1.1A according to the invention is represented comprising a stack, or series, of layers. This membrane is intended to envelop a thermal insulation panel, in particular a vacuum insulation panel (VIP). An inner face 3A of the membrane is distinguished, which is intended to be oriented on the side of the insulation panel in the enveloped configuration thereof, and an outer face 5A of the membrane, which is opposite thereto.

The PET support layer 2 defines the outer face 5A of the membrane 1.1A. It is coated on its inner face with a planarizing layer 4 based on a urethane/acrylate resin. The planarizing layer 4 defines a planarized upper surface 11A directly coated with a thin metallic layer 6 based on aluminum, having a thickness less than or equal to 200 nm. A heat-sealable layer 8A made of polyethylene is added on the inner face of the metallic layer 6. The heat-sealable layer 8A may be, in particular, extruded on the metallic layer 6 or bonded on the metallic layer 6 by means of a layer of adhesive. The heat-sealable layer 8A makes it possible, after folding and heat sealing, to seal the membrane in the form of a gastight envelope. The heat-sealable layer 8A defines the inner face 3A of the membrane 1.1A.

In the variant of FIG. 1B, a heat-sealable layer 8B made of polyethylene is added to a PET support layer 2 and defines the inner face 3B of the membrane 1.1B. The heat-sealable layer 8B may be, in particular, extruded on the support layer 2 or bonded on the support layer 2 by means of a layer of adhesive. The support layer 2 is coated on its outer face with a planarizing layer 4 based on a urethane/acrylate resin. The planarizing layer 4 defines a planarized upper surface 11B directly coated with a thin metallic layer 6 based on aluminum. The layer 6 is itself coated with a protective layer 12 made of PET or nylon that defines the outer face 5B of the membrane 1.1B.

The Support Layer (Cs):

The role of the support layer is to provide the other layers of the membrane with a support having sufficient mechanical strength to carry out the manufacturing process, to enable the stack to be handled and to allow the use of the membrane, in particular in the manufacture of thermal insulation panels, in particular vacuum insulation panels (VIPs).

The support layer (Cs) defines two main surfaces, one of which may form the outer face of the membrane, as illustrated in FIG. 1A.

In a known manner, the support layer is based on polymer material.

It may be formed from a single layer of polymer material, or it may be formed from a stack of layers of a same material or of different materials, assembled for example by coextrusion, hot lamination or by bonding.

Among the preferred polymer materials that are incorporated into the composition of the support layer, mention may be made of: polyesters, such as for example polyethylene terephthalate (PET), polyethylene naphthalate (PEN); polyamides (nylon) such as for example nylon-6, nylon-6,6, nylon-6,10, nylon-6,12, nylon-11, nylon-12; copolymers of ethylene and vinyl alcohol (EVOH); polypropylene (PP); polyvinylidene fluoride (PVDF); mixtures of these materials.

The support layer is obtained from at least one composition of at least one polymer material. This composition may in addition comprise additives known for the manufacture of polymer material films, such as for example dyes, pigments, UV stabilizers, plasticizers, lubricants, fillers.

Preferentially, the support layer comprises polyethylene terephthalate.

According to one preferred embodiment of the invention, the support layer essentially consists of polyethylene terephthalate.

The thickness of the support layer is advantageously from 5 to 500 μm, preferentially from 10 to 200 μm.

The process for manufacturing the support layer advantageously comprises the extrusion of a polymer material film. It may comprise other steps such as for example the stretching or blowing of a polymer material film. The process for manufacturing the support layer may comprise coextrusion, hot lamination or bonding of several layers of polymer materials when the support layer itself consists of a stack of layers.

The Planarizing Layer (Cp):

The planarizing layer (Cp), intermediate between the support layer (Cs) and the metallic layer (Cm), defines a planarized surface, opposite the surface in contact with the support layer. The metallic layer will be deposited on the planarized surface.

The planarized surface has a mean surface roughness Rq less than or equal to 1 nm, where Rq is the root-mean-square deviation as defined in the ISO 4287 standard, measured by atomic force microscopy (AFM) over a surface area of 5×5 μm². Preferably, the planarizing layer has a mean surface roughness Rq less than or equal to 0.5 nm.

The planarizing layer advantageously consists of at least one material resulting from the curing of a resin composition.

The resin composition used to form the planarizing layer preferentially comprises one or more precursors of polymers selected from: polyesters, polyurethanes, polyester/polyurethane copolymers, silanes, siloxanes, silane-modified polyesters, silane-modified polyurethanes, polyester/siloxane copolymers, polyurethane/siloxane copolymers.

The expression “precursors of polymers and copolymers” is understood to mean monomers, oligomers, prepolymers, polymers and copolymers, crosslinking agents.

The resin composition preferentially comprises one or more components selected from: acrylic, methacrylic, acrylate, methacrylate, urethane, monoisocyanate, polyisocyanate, alcohol, polyol, polyether, polyepoxide, silane, siloxane, silanol precursors.

Advantageously, the resin composition used to form the planarizing layer comprises at least one polyfunctional precursor, that is to say comprising at least two reactive functions, of identical or different nature, such as for example: urethane/acrylate or methacrylate oligomers; polyisocyanates; RSi(OH)₃ silanols, in which R represents an organic group that comprises at least one reactive function, such as a vinyl, epoxy, acrylate function.

Urethane/acrylate or urethane/methacrylate oligomers that are monofunctional or multifunctional in acrylate and/or methacrylate end groups are described for example in WO 2014/188116.

RSi(OH)₃ silanols, the R group of which comprises a reactive function, such as a vinyl, epoxy, acrylate function, are described for example in US 2010/0154886.

According to a first preferred embodiment of the invention, the planarizing resin composition comprises at least one precursor selected from polyfunctional (meth)acrylates. Advantageously, according to this embodiment, the planarizing resin composition comprises at least one precursor selected from those having a functionality greater than or equal to 3, that is to say having for example three or four reactive groups, or more. Advantageously, according to this embodiment, the planarizing resin composition comprises at least one precursor selected from urethane/(meth)acrylates and at least one precursor selected from difunctional and trifunctional (meth)acrylates.

Preferably, according to this embodiment, the planarizing resin composition comprises at least:
a tetrafunctional urethane/alkyl (meth)acrylate oligomer,
a difunctional alkyl (meth)acrylate monomer,
a trimethylolpropane triacrylate monomer.

Advantageously, according to this embodiment, the planarizing resin composition comprises at least:
30% to 90% of at least one tetrafunctional urethane/alkyl (meth)acrylate oligomer,
5% to 40% of at least one difunctional alkyl (meth)acrylate monomer,
5% to 40% of trimethylolpropane triacrylate,

the percentages being given by weight of active material relative to the total weight of the polymer precursors of the planarizing resin composition.

Even more advantageously, according to this embodiment, the planarizing resin composition comprises at least:
50% to 70% of at least one tetrafunctional urethane/alkyl (meth)acrylate oligomer,
15% to 25% of at least one difunctional alkyl (meth)acrylate monomer,
15% to 25% of trimethylolpropane triacrylate,

the percentages being given by weight of active material relative to the total weight of the polymer precursors of the planarizing resin composition.

The resin composition may also comprise one or more components selected from: mineral nanoparticles, preferentially having a size less than or equal to 25 nm, such as inorganic oxides, for example silica, titanium oxide or zirconium oxide nanoparticles. Advantageously, silica nanoparticles are selected. Preferably, the inorganic particles have a size ranging from 5 nm to 15 nm. Mention may be made, for example, of the colloidal silica dispersions Ludox-SM®, Ludox-LS®. When they are present, the mineral nanoparticles advantageously represent from 5% to 40% by weight, relative to the total weight of the planarizing resin composition.

The resin composition may also comprise one or more components selected from: crosslinking catalysts, such as for example:
metal salts of carboxylic acids, in particular: sodium acetate, potassium acetate, sodium formate, potassium formate, zinc, tin, magnesium, cobalt, calcium, titanium or zirconium acetylacetonates; zinc stearate;
metal oxides such as zinc oxide, antimony oxide, indium oxide;
metal alkoxides such as titanium tetrabutoxide, titanium propoxide, zirconium, niobium or tantalum alkoxides;
alcoholates and hydroxides of alkali metals, alkaline earth metals and rare earth hydroxides, such as sodium methoxide.

Advantageously, the catalyst represents from 0.1% to 10% by weight relative to the total weight of the resin precursors.

The planarizing resin composition may be in the form of a solution in a solvent, for instance water, an alcohol, such as methanol, ethanol, propanol, a ketone, such as acetone, methyl ethyl ketone. It may also be composed solely of active materials, which, as a mixture, are liquid.

The planarizing resin composition is deposited in a known manner by a liquid route on the inner face of the support layer then cured by application of an appropriate treatment, such as a rise in temperature or an irradiation treatment, for example a UV irradiation. In certain cases, the planarizing resin composition is cured by simple exposure to air. When the planarizing resin composition has been deposited in the form of a solution in a solvent, a drying step is advantageously provided before the curing.

The methods of application by the liquid route include: coating, in particular roll coating, brush coating, slot-die coating; vaporization; dip coating; spin coating; Meyer rod coating.

Advantageously, the amount of resin composition deposited on the support layer is adapted in order to form a dry resin layer having a thickness ranging from 0.1 to 100 μm, preferentially from 0.5 to 25 μm, better still from 1 to 5 μm.

Planarizing resin compositions capable of being used in the present invention have been described for other applications in documents WO 2010/078233, US 2010/0154886.

The Metallic Layer (Cm):

In a known manner, the metallic layer is made of metal, or made of metal oxide, and has a thickness less than or equal to 200 nm. The role of this layer is to be gastight, in particular with respect to water vapor and to air. It is deposited directly on the planarizing layer.

Among the metals that can be used to form the metallic layer, mention may be made of: aluminum, iron, chromium, nickel, platinum, gold, silver.

Among the metal oxides that can be used to form the metallic layer, mention may be made of:
oxides of metals from groups 2 (formerly IIA) and 13 (formerly IIIA), and of transition metals (groups 3 to 12, formerly IB to VIIIB) of the periodic table of the elements, such as for example: Be, Mg, Ca, Sr, Ba, Al, Ga, In, Ti, Ti, Cu, Ni, Cr, Zn, Sb;
silicon oxides, in particular selected from those corresponding to the formula SiO, with x≥2.

Preferably, the metallic layer is made of aluminum.

The metallic layer is deposited on the planarizing layer by any method that makes it possible to obtain a deposit having a thickness of less than or equal to 200 nm.

For example, the metallic layer is advantageously deposited by evaporation; by sputtering, in particular magnetron sputtering; by vapor deposition (or CVD (chemical vapor deposition)); by electron beam; by atomic layer deposition (ALD). Preferentially, the metallic layer is deposited by evaporation or by magnetron sputtering.

The Heat-Sealable Layer (Ct):

The heat-sealable layer (Ct) defines two surfaces, one of which forms the inner face of the membrane.

The heat-sealable layer may consist of one layer or of several successive stacked layers of thermofusible materials.

As material capable of being used to form the heat-sealable layer, mention may be made of: polyolefin homopolymers and copolymers, polyesters.

Mention may be made, as examples of polyolefin homopolymers and copolymers, of: polyethylenes and in particular linear low-density polyethylene (LLDPE), medium-density polyethylene, high-density polyethylene (HDPE); polybutylene (PB); ethylene/vinyl acetate copolymers (EVA); polypropylene (PP); ethylene/ethyl acrylate copolymers; ethylene/acrylic acid copolymers; ethylene/methacrylic acid copolymers; ethylene/propylene copolymers; ionomer polymers (IO); mixtures of these materials.

Mention may be made, as examples of polyesters, of: amorphous polyethylene terephthalate (PET).

Preferentially, the heat-sealable layer is based on polyethylene.

The heat-sealable layer is obtained from a composition based on polymer materials that may in addition comprise, in a known and nonlimiting manner: fillers, plasticizers.

Advantageously, the thermofusible polymers represent at least 95% by weight of the total weight of the heat-sealable layer, advantageously at least 98%.

Even more preferentially, the polyolefin homopolymers and copolymers represent at least 95% by weight of the total weight of the heat-sealable layer, advantageously at least 98%.

According to one preferred embodiment of the invention, the heat-sealable layer essentially consists of polyethylene.

The heat-sealable layer may be produced by extrusion or coextrusion of one or more of the materials mentioned above. It may be assembled with the other layers by extrusion coating, by hot or cold lamination, by means of a layer of adhesive.

The thickness of the heat-sealable layer is preferably from 20 to 200 μm, and particularly preferably from 25 to 100 μm.

Stack:

Surprisingly, the stack of layers defining the membranes of the invention has gas barrier properties that are greater than the sum of the barrier properties of the various layers taken individually.

Advantageously, the stack consists of layers that have substantially the same dimensions, so that the stack consists, over its entire surface, of the same superpositions of layers.

Other Layers:

The composite film may also comprise one or more layers of at least one other material.

For example, provision may be made to coat the support layer with a primer coating layer that facilitates the adhesion of the planarizing layer to the support layer. In particular, use may be made, in a known manner, of a layer based on optionally crosslinked, (meth)acrylic or (meth)acrylate polyester resin in order to promote the adhesion.

Among the other layers capable of being used in the manufacture of the membrane of the invention, mention may be made of: an antistatic layer, a layer having fire-retardant properties.

As illustrated in FIG. 1B, the stack may comprise a protective layer 12, for example made of PET or of Nylon®, on the metallic layer, the protective layer acting in particular as outer layer.

Multiple Stacks:

The stack of a planarizing layer (Cp) and of a metallic layer (Cm) of at least one metal or one metal oxide having a thickness less than or equal to 200 nm, defines a gastight module (Meg).

According to the invention, provision may be made to stack several gastight modules, so as to reinforce the gas barrier properties of the membranes of the invention.

It is possible to stack gastight modules consisting of layers that are identical or different as regards their chemical nature, their composition, their thickness.

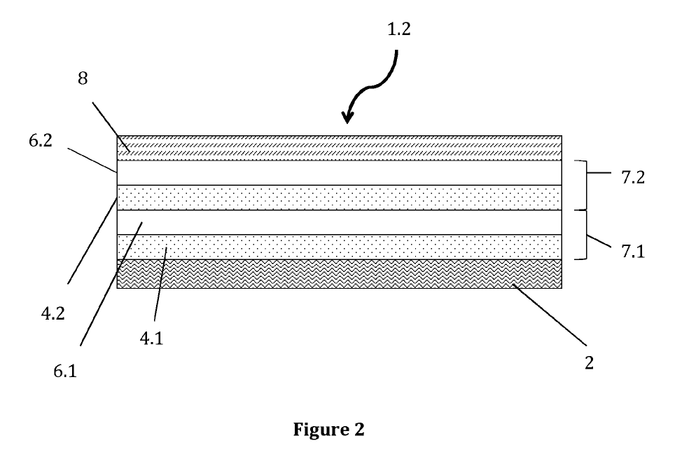

For example, as represented in FIG. 2, and as illustrated by example 2 from the experimental section, it is possible to form, according to the invention, a membrane 1.2 having gas barrier properties by superposing: a support layer 2, then a first planarizing layer 4.1, followed by a first metallic layer 6.1, which form a first gastight module 7.1, then a second planarizing layer 4.2, followed by a second metallic layer 6.2, which form a second gastight module 7.2, and finally a heat-sealable layer 8.

The stack of a support layer (Cs) made of polymer material, a planarizing layer (Cp) and a metallic layer (Cm) of at least one metal or one metal oxide having a thickness less than or equal to 200 nm, defines a supported module (Msp).

It is possible, according to the invention, to stack supported modules consisting of layers that are identical or different as regards their chemical nature, their composition, their thickness.

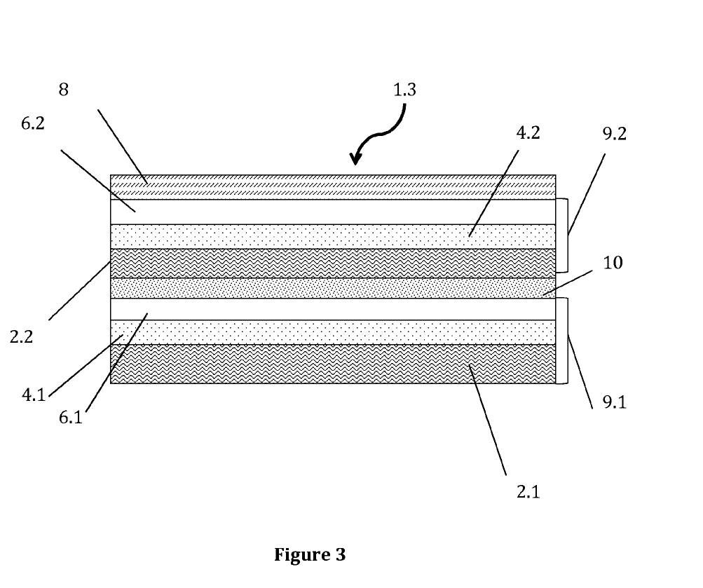

For example, as represented in FIG. 3, and as illustrated by example 3 from the experimental section, it is possible to form, according to the invention, a membrane 1.3 having gas barrier properties by superposing: a first support layer 2.1, then a first planarizing layer 4.1, followed by a first metallic layer 6.1, which form a first supported module 9.1; then an adhesive layer 10; then a second support layer 2.2, then a second planarizing layer 4.2, followed by a second metallic layer 6.2, which form a second supported module 9.2; and finally a heat-sealable layer 8.

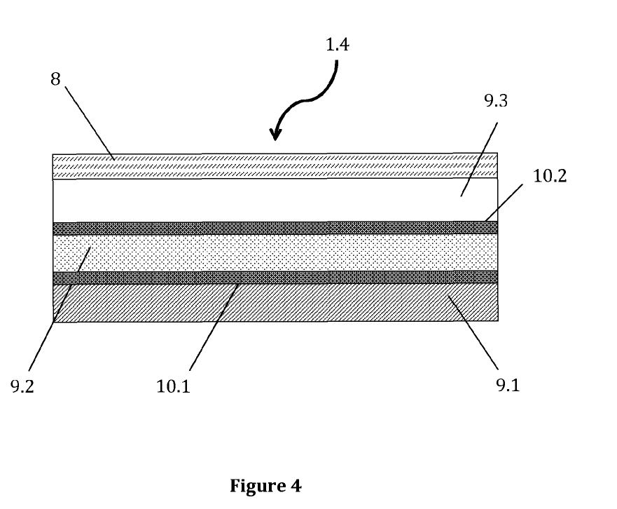

Represented in FIG. 4, and as illustrated by example 4 from the experimental section, is a stack of layers comprising a first supported module 9.1, then an adhesive layer 10.1, a second supported module 9.2, an adhesive layer 10.2, a third supported module 9.3, and finally a heat-sealable layer 8. The three supported modules may have identical or different compositions and thicknesses.

According to the invention, the stack may comprise one or more adhesive layers, for example based on acrylic and/or polyurethane resin between two layers, or between two gastight modules or between two supported modules.

Process for Manufacturing Multilayer Membranes:

The multilayer membranes of the invention may be manufactured in the form of a continuous strip comprising the stack of the various layers that have been described above, deposited successively by means of the processes described above and which will be explained in detail in the experimental section. After the manufacturing of the strip, it is cut to the desired dimensions.

According to another embodiment, it is possible to choose to directly manufacture multilayer membranes having the desired dimensions.

Properties and Characterization of the Multilayer Membranes:

The multilayer membranes of the invention are characterized by their gas barrier properties, in particular oxygen barrier property and water vapor barrier property. The latter property is particularly important, since it is known in the field of thermal insulation panels of VIP type that the penetration of moisture inside the membrane is an important factor in the degradation of the thermal insulation properties.

The water vapor transmission rate (WVTR) may be evaluated by any known method, in particular by means of the CRDS (cavity ring-down spectroscopy) method described in US 2012/062896 A1, or the ASTM F1249-90 method.

The oxygen transmission rate (OTR) may be evaluated by any known method, in particular by means of the ISO 14663-2 method, or the ASTM D3985 method.

The multilayer membranes of the invention are particularly suitable for the manufacture of vacuum insulation panels (VIPs) intended for the thermal insulation of a building, for the insulation of internal walls or external walls. They may also be used in other applications, such as for example the manufacture of vacuum insulation panels for electric household appliances.

Experimental Section:

I—Equipment and Methods:

Materials:
Support layer: formed from a Melinex® ST505 polyethylene terephthalate PET sold by DuPont®.
Planarizing layer (Cp): formed from a mixture of resin precursors described in table 1 below, to which a polymerization initiator is added.

TABLE 1
composition of the planarizing layer

| | Amounts | | |
|---|---|---|---|
| Raw | (% by weight) | | |
| materials | (*) | Chemical nature | Supplier |
| Sartomer ® | 60 | Tetrafunctional urethane/ | Arkéma |
| CN 9276 | | aliphatic acrylate | |
| Sartomer ® | 20 | Difunctional acrylate | Arkéma |
| SR 833S | | monomer | |
| Sartomer ® | 20 | Trimethylolpropane | Arkéma |
| SR 351 | | triacrylate | |
| Total | 100 | | |
| Irgacure ® | 5 | Polymerization initiator | CIBA |
| 500 | | | |

(*) % given by weight of commercial raw material, the components being diluted to 50% in methyl ethyl ketone.

Metallic layer: aluminium (Al).
Adhesive (Adh): the adhesive composition comprises an Adcote® 76R44 polyester resin sold by Dow Chemical (based on polyester and toluene) diluted in ethyl acetate in order to have a final solid concentration of 20% by weight. The crosslinker is Adcote® Catalyst 9L10 also by Dow Chemical, used in an amount of around 7% by weight relative to the weight of resin (% calculated as active material). The composition is mixed for 30 min at ambient temperature, deposited on the substrate by wet coating then dried at 110° C. for 30 s, in order to have a layer of around 3-4 μm.
Heat-sealable layer: polyethylene (PE) of high or low density having a thickness of 50 μm.

Methods:
Deposition of a planarizing layer: a layer of resin having the composition given in table 1 is deposited on the support layer with a Meyer rod, model no. 0, in order to have a thickness of 4 μm. After drying, the layer has a thickness of 2 μm.
Deposition of a metallic layer: after deposition of the planarizing layer on the support layer, a layer of aluminium having a thickness of 100 nm is deposited on the planarizing layer by magnetron sputtering using an aluminium target, under a pressure of 0.2 Pa in a pure argon atmosphere.
Measurement of the roughness: Rq, as defined in the ISO 4287 standard, is measured by atomic force microscopy (AFM) over a surface area of 5×5 μm².
Measurement of the water vapor permeability: the water vapor transmission rate (WVTR) is evaluated in g/m²/day at 38° C., 95% humidity according to the CRDS method described in US 2012/062896 A1.

II—Materials Prepared:

By means of the materials and processes described above, membranes having the following characteristics were prepared:

### EXAMPLES ACCORDING TO THE INVENTION

TABLE 2
Examples of stacks according to the invention

| Example | | |
|---|---|---|
| No. | Stack | Thickness |
| Ex1 | PET/Cp/Al | 50 μm/2 μm/100 nm |
| Ex2 | PET/Cp/Al/Cp/Al | 50 μm/2 μm/100 nm |
| | (FIG. 2) | 2 μm/100 nm |
| Ex3 | PET/Cp/Al/Adh/PET/Cp/Al | 50 μm/2 μm/100 nm/ |
| | (FIG. 3) | Adh/ |
| | | 50 μm/2 μm/100 nm |
| Ex4 | PET/Cp/Al/Adh/PET/Cp/Al/ | 50 μm/2 μm/100 nm/ |
| | Adh/PET/Cp/Al | Adh/ |
| | (FIG. 4) | 50 μm/2 μm/100 nm/ |
| | | Adh/ |
| | | 50 μm/2 μm/100 nm |
| Ex5 | PET/Cp/Al//PE | 50 μm/2 um/100 nm/ |
| | (FIG. 1A) | 50 μm |

The roughness of the planarizing layers in each of the examples is evaluated after deposition, it is less than 0.5 nm.

### Comparative Examples

TABLE 3
Comparative example

| Example | | |
|---|---|---|
| No. | Stack | Thickness |
| CEx1 | PET/Al | 50 μm/100 nm |
| CEx2 | PET/Al/Cp/Al | 50 μm/100 nm/2 μm/100 nm |
| CEx3 | PET/Al/Adh/PET/Al | 50 μm/100 nm/Adh/50 μm/100 nm |
| CEx4 | PET/Al/Adh/PET/Al/ | 50 μm/100 nm/Adh/50 μm/100 nm/ |
| | Adh/PET/Al | Adh/50 μm/100 nm |

III—Results:

| Example | Number of samples | Water vapor permeability: |
|---|---|---|
| No. | measured | WVTR (g/m²/day) |
| Ex1 | 4 | 25 × 10⁻³ |
| Ex2 | 2 | 0.9 × 10⁻³ |
| CEx1 | 2 | >0.1 |
| | | (apparatus saturated) |
| CEx2 | 2 | 9.4 × 10⁻³ |

### Example 5

the presence of the polyethylene heat-sealable layer did not significantly modify the water vapor permeability properties of the membrane relative to example 1.

1. A multilayer membrane comprising a stack of layers, including one heat-sealable layer forming a peripheral face of the multilayer membrane and at least, in order, the following sequence:
a support layer made of polymer material,
a metallic layer made of at least one material selected from: a metal and a metal oxide, having a thickness less than or equal to 200 nm, and
at least one planarizing layer between the support layer and the metallic layer, the planarizing layer defining a planarized surface which has a mean surface roughness Rq less than or equal to 1 nm.

2. The multilayer membrane as claimed in claim 1, wherein the planarizing layer results from the curing of a resin composition comprising one or more precursors of polymers selected from: polyesters, polyurethanes, polyester/polyurethane copolymers, silanes, siloxanes, silane-modified polyesters, silane-modified polyurethanes, polyester/siloxane copolymers, polyurethane/siloxane copolymers.

3. The multilayer membrane as claimed in claim 2, wherein the planarizing layer results from the curing of a resin composition comprising one or more precursors of polymers selected from: alkyl acrylates, alkyl methacrylates, urethanes/acrylates and urethanes/methacrylates.

4. The multilayer membrane as claimed in claim 3, wherein the planarizing layer results from the curing of a resin composition comprising at least:
a tetrafunctional urethane/alkyl (meth)acrylate oligomer,
a difunctional alkyl (meth)acrylate monomer,
a trimethylolpropane triacrylate monomer.

5. The multilayer membrane as claimed in claim 1, wherein the planarizing layer has a thickness between 0.1 μm and 100 μm.

6. The multilayer membrane as claimed in claim 1, wherein the metallic layer is made of aluminum.

7. The multilayer membrane as claimed in claim 1, wherein the support layer is based on polyethylene terephthalate.

8. The multilayer membrane as claimed in claim 1, wherein the stack of the planarizing layer and of e metallic layer of at least one metal or one metal oxide having a thickness less than or equal to 200 nm, defines a gastight module, the multilayer membrane comprising at least, in order:
the support layer made of polymer material,
a first gastight module,
a second gastight module, identical to or different from the first gastight module.

9. The multilayer membrane as claimed in claim 1, wherein the stack of the support layer made of polymer material, of the planarizing layer and of the metallic layer of at least one metal or one metal oxide having a thickness less than or equal to 200 nm, defines a supported module, the multilayer membrane comprising at least, in order:
a first supported module,
an adhesive layer,
a second supported module, identical to or different from the first supported module.

10. The multilayer membrane as claimed in claim 9, which comprises at least, in order:
the first supported module,
a first adhesive layer,
the second supported module,
a second adhesive layer,
a third supported module, identical to or different from the first supported module, identical to or different from the second supported module.

11. A vacuum insulation panel comprising at least one rigid panel made of a porous material having insulating properties and an envelope composed of at least one multilayer membrane as claimed in claim 1.

12. A process for manufacturing a multilayer membrane as claimed in claim 1, the process comprising:
providing at least one support layer;
depositing at least one metallic layer having a thickness less than or equal to 200 nm; and
depositing a planarizing layer between the support layer and the metallic layer.

13. The process as claimed in claim 12, wherein the depositing of the planarizing layer is carried out by a liquid route.

14. The process as claimed in claim 12, wherein the depositing of the metallic layer is carried out by evaporation or sputtering.

15. An envelope of a vacuum insulation panel, comprising:
a multilayer membrane as claimed in claim 1.

16. The multilayer membrane as claimed in claim 1, wherein the planarized surface has a mean surface roughness Rq less than or equal to 0.5 nm.

17. The multilayer membrane as claimed in claim 5, wherein the thickness of the planarizing layer is between 0.5 μm and 25 μm.

18. The multilayer membrane as claimed in claim 5, wherein the thickness of the planarizing layer is between 1 μm and 5 μm.

19. The process as claimed in claim 12, wherein the depositing of the planarizing layer is carried out by roll coating or brush coating, slot-die coating, vaporization, dip coating, spin coating or Meyer rod coating.

20. The process as claimed in claim 12, wherein the depositing of the metallic layer is carried out by magnetron sputtering.
